(19) United States
(12) Patent Application Publication
(10) Pub. No.: US 2024/0040809 A1
(43) Pub. Date: Feb. 1, 2024

(54) OPTICAL SENSOR AND DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventors: Manman Ding, Wuhan, Hubei (CN); Wenxu Xianyu, Wuhan, Hubei (CN); Chongpeng Ruan, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 17/622,852

(22) PCT Filed: Dec. 21, 2021
(86) PCT No.: PCT/CN2021/139847

§ 371 Date: Jun. 22, 2023

(30) Foreign Application Priority Data
Dec. 14, 2021 (CN) 202111526446.4

(51) Int. Cl. H10K 30/80; H10K 39/34

(52) U.S. Cl. CPC H10K 30/80; H10K 39/34

(57) ABSTRACT

The present application provides an optical sensor and a display panel. The display panel comprises the optical sensor, and the optical sensor comprises a substrate, a photosensitive device and a filter layer. The filter layer is configured to have a lens shape. It can not only achieve the absorption of single-band light, but also increase the amount of light entering the optical sensor. Meanwhile, the traditional process of preparing the microlens film layer and the filter layer can be omitted, thereby simplifying the process flow of the optical sensor and the display panel and reducing the production cost.

### FIELD OF THE INVENTION

The present invention relates to a display technology field, and more particularly to an optical sensor and a display panel.

### BACKGROUND OF THE INVENTION

In recent years, due to the photoelectric tunability of organic materials, single-band and full-band organic photodiodes have been realized. Compared with inorganic photodiodes, organic photodiode (OPD) possesses the characteristics of high flexibility, large area and more types, so it has also been developed rapidly. At present, organic photodiodes have been used in X-ray, biological detection, under-screen, image sensing and other fields.

To realize the absorption of organic photodiodes for single-band light, one is to adjust the material of the active layer, but the development cost of the material is relatively high; the other is to utilize selective light-transmitting color filters, the traditional color filters are mostly produced by photolithography, which also has the problems of high production costs and relatively complicated processes.

In summary, the existing optical sensor has the problems of high cost and complicated process for achieving single-band light absorption. Therefore, there is a need to provide an optical sensor and a display panel to improve this defect.

### SUMMARY OF THE INVENTION

The embodiments of the present application provide an optical sensor and a display panel, which are employed to solve the problems of the existing optical sensors that the cost of achieving single-band light absorption is relatively high and the process is relatively complicated.

The embodiment of the present application provides an optical sensor, comprising:
a substrate;
a photosensitive device arranged on the substrate; and
a filter layer arranged on a light incident side of the photosensitive device;
wherein the filter layer possesses a lens shape.

According to an embodiment of the present application, the optical sensor comprises a plurality of accommodating cavities, which are spaced apart;
wherein the filter layer is at least partially arranged in the accommodating cavity.

According to an embodiment of the present application, the filter layer comprises a bottom surface and a top surface, and the bottom surface is laid flat on the bottom of the accommodating cavity, and the top surface is a curved surface protruding toward a side away from the bottom surface.

According to an embodiment of the present application, the bottom surface is directly connected to the top surface.

According to an embodiment of the present application, the filter layer further comprises a side surface, and the side surface extends along a side wall of the accommodating cavity and is connected to the top surface and the bottom surface, respectively.

According to an embodiment of the present application, an orthographic projection of the filter layer on the substrate covers an orthographic projection of the accommodating cavity on the substrate;
the orthographic projection of the filter layer on the substrate and an orthographic projection of any adjacent filter layer on the substrate are spaced apart from each other.

According to an embodiment of the present application, the optical sensor comprises a defining layer, the defining layer comprises a photosensitive opening, and the photosensitive opening penetrates the defining layer in a thickness direction of the defining layer;
the photosensitive device comprises a photosensitive layer, and the photosensitive layer is arranged in the photosensitive opening.

According to an embodiment of the present application, the optical sensor further comprises a cathode layer and an encapsulation layer, and the cathode layer and the encapsulation layer are sequentially stacked on a side of the defining layer away from the substrate and cover the photosensitive layer;
wherein a part of the encapsulation layer corresponding to the photosensitive opening is recessed toward the photosensitive opening and forms the accommodating cavity.

According to an embodiment of the present application, a material of the photosensitive layer comprises at least one of small molecule organic materials, polymer materials and quantum dot materials.

According to an embodiment of the present application, the filter layer comprises a combination of at least one or more of a red filter layer, a green filter layer, a blue filter layer and a near-infrared filter layer.

The embodiment of the present application further provides a display panel, comprising an optical sensor and a light-emitting device, wherein a light-emitting device is arranged on a substrate and is spaced apart from a photosensitive device;
wherein the optical sensor comprises:
a substrate;
a photosensitive device arranged on the substrate; and
a filter layer arranged on a light incident side of the photosensitive device;
wherein the filter layer possesses a lens shape.

According to an embodiment of the present application, the optical sensor comprises a plurality of accommodating cavities, which are spaced apart;
wherein the filter layer is at least partially arranged in the accommodating cavity.

According to an embodiment of the present application, the filter layer comprises a bottom surface and a top surface, and the bottom surface is laid flat on the bottom of the accommodating cavity, and the top surface is a curved surface protruding toward a side away from the bottom surface.

According to an embodiment of the present application, the bottom surface is directly connected to the top surface.

According to an embodiment of the present application, the filter layer further comprises a side surface, and the side surface extends along a side wall of the accommodating cavity and is connected to the top surface and the bottom surface, respectively.

According to an embodiment of the present application, an orthographic projection of the filter layer on the substrate covers an orthographic projection of the accommodating cavity on the substrate;
the orthographic projection of the filter layer on the substrate and an orthographic projection of any adjacent filter layer on the substrate are spaced apart from each other.

According to an embodiment of the present application, the optical sensor comprises a defining layer, the defining layer comprises a photosensitive opening, and the photosensitive opening penetrates the defining layer in a thickness direction of the defining layer;
the photosensitive device comprises a photosensitive layer, and the photosensitive layer is arranged in the photosensitive opening.

According to an embodiment of the present application, the optical sensor further comprises a cathode layer and an encapsulation layer, and the cathode layer and the encapsulation layer are sequentially stacked on a side of the defining layer away from the substrate and cover the photosensitive layer;
wherein a part of the encapsulation layer corresponding to the photosensitive opening is recessed toward the photosensitive opening and forms the accommodating cavity.

According to an embodiment of the present application, a material of the photosensitive layer comprises at least one of small molecule organic materials, polymer materials and quantum dot materials.

According to an embodiment of the present application, the light-emitting device and the photosensitive device are arranged in a same layer.

The benefits of the present disclosure are: the embodiment of the present application provides an optical sensor and a display panel. The display panel comprises the optical sensor, and the optical sensor comprises a substrate, a photosensitive device and a filter layer. The photosensitive device is arranged on the substrate. The filter layer is arranged on a light incident side of the photosensitive device. With arranging the filter layer to have a lens shape, light is converged to the optical sensor. It can not only achieve the absorption of single-band light, but also increase the amount of light entering the optical sensor. Meanwhile, the traditional process of preparing the microlens film layer and the filter layer can be omitted, thereby simplifying the process flow of the optical sensor and the display panel and reducing the production cost.

### BRIEF DESCRIPTION OF THE DRAWINGS

In order to more clearly illustrate the embodiments of the present disclosure or prior art, the following figures will be described in the embodiments are briefly introduced. It is obvious that the drawings are merely some embodiments of the present disclosure, those of ordinary skill in this field can obtain other figures according to these figures without paying the premise.

FIG. 1 is a structural diagram of a first optical sensor provided by an embodiment of this application;

FIG. 2 is a structural diagram of a second optical sensor provided by an embodiment of this application;

FIG. 3 is a structural diagram of a third optical sensor provided by an embodiment of this application;

FIG. 4 is a structural diagram of a wearable device provided by an embodiment of the application;

FIG. 5 is a structural diagram of a display panel provided by an embodiment of the application.

### DETAILED DESCRIPTION OF PREFERRED EMBODIMENTS

The following descriptions for the respective embodiments are specific embodiments capable of being implemented for illustrations of the present application with referring to appended figures. The terms of up, down, front, rear, left, right, interior, exterior, side, etcetera in the present application are merely directions of referring to appended figures. Thus, the used directional terms are used to describe and understand the present disclosure, but the present disclosure is not limited thereto. In the figure, units with similar structures are denoted by the same reference numerals.

The present disclosure will be further described in detail with the accompanying drawings and the specific embodiments.

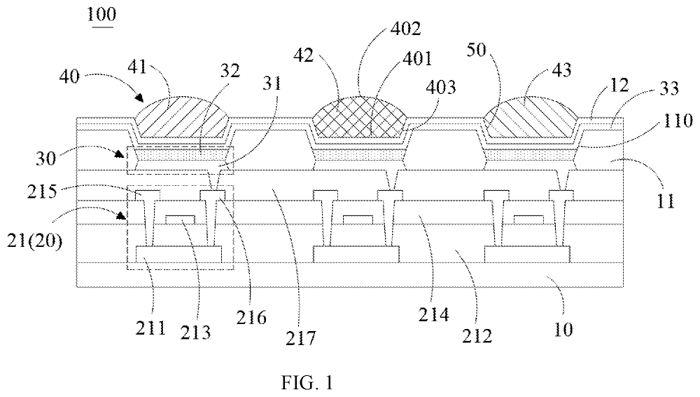

The embodiment of the present application provides an optical sensor, as shown in FIG. 1. FIG. 1 is a structural diagram of a first optical sensor provided by an embodiment of this application. The optical sensor 100 comprises a substrate 10, a driving circuit layer 20, a photosensitive device 30 and a filter layer 40. The driving circuit layer is arranged on the substrate 10. The photosensitive device 30 is arranged on the driving circuit layer, and electrically connected to the driving circuit in the driving circuit layer. The filter layer 40 is arranged on a light incident side of the photosensitive device 30. The light irradiated to the filter layer 40 can be filtered, so that the light in the set wavelength range can pass through the filter layer 40 and irradiate to the photosensitive device 30. The photosensitive device 30 can absorb light of the specific wavelength to convert the optical signal of the specific wavelength into a corresponding electrical signal.

In the embodiment of the present application, the filter layer 40 possesses a lens shape. With arranging the filter layer 40 to possess a lens shape, the filter layer 40 can adjust the path of the received light to be converged to the photosensitive device 30 while the filter layer 40 achieves the filter function, thereby increasing the amount of light entering the photosensitive device 30, so that the accuracy of the photosensitive device 30 can be improved.

Furthermore, the filter layer 40 comprises a combination of at least one or more of a red filter layer, a green filter layer, a blue filter layer and a near-infrared filter layer. The optical sensor may comprise a plurality of photosensitive devices 30, and the plurality of photosensitive devices 30 are arranged in an array on a side of the substrate 10. The optical sensor may further comprise a plurality of filter layers 40, and each of the photosensitive devices 30 possesses a corresponding filter layer 40, so that the photosensitive device 30 corresponding to the filter layer 40 can receive light of a preset single band.

In one of the embodiments, as shown in FIG. 1, the filter layer 40 comprises a red filter layer 41, a green filter layer 42 and a blue filter layer 43. The red filter layer 41, the green filter layer 42 and the blue filter layer 43 are spaced apart from one another, and respectively correspond to different photosensitive devices 30. The red filter layer 41, the green filter layer 42 and the blue filter layer 43 can separate red, green, and blue colors, respectively. The combination of the red filter layer 41, the green filter layer 42 and the blue filter layer 43 in the filter layer 40 can be applied to image sensing.

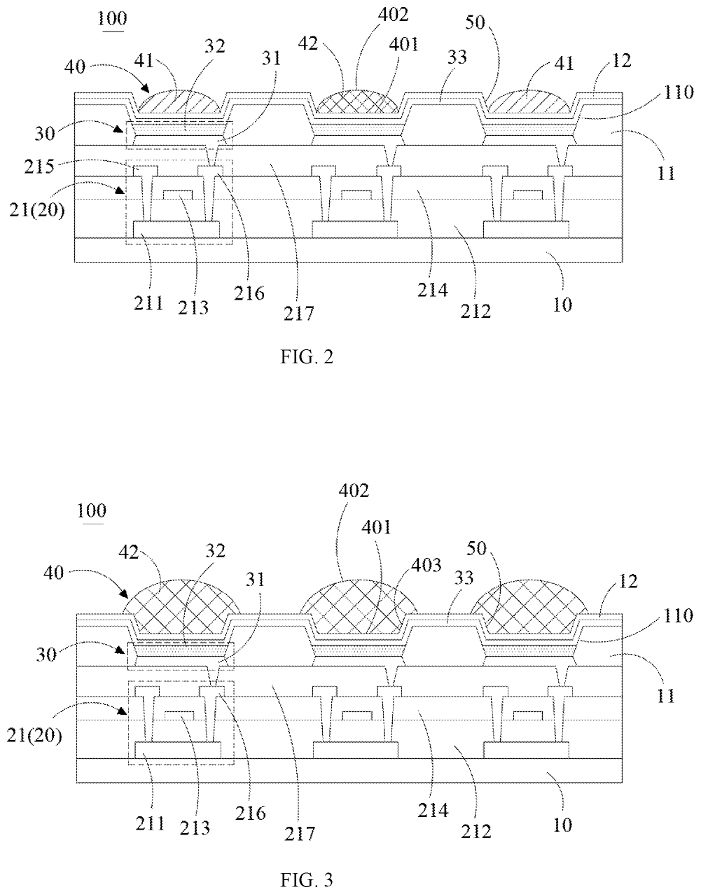

In one of the embodiments, as shown in FIG. 2, FIG. 2 is a structural diagram of a second optical sensor provided by an embodiment of this application. The filter layer 40 comprises two different color filter layers, a red filter layer 41 and a green filter layer 42, respectively. The red filter layer 41 and the green filter layer 42 are spaced apart from each other and respectively correspond to different photosensitive devices 30. The combination of the red filter layer 41 and the green filter layer 42 can be applied to blood oxygen detection.

Since there is a certain ratio of oxygenated hemoglobin (HbO₂) and reduced hemoglobin (Hb) contained in the blood, it is the so-called oxygen content. Oxygenated hemoglobin (HbO₂) and reduced hemoglobin (Hb) have almost the same absorption rate at green light, and reduced hemoglobin (Hb) possesses a higher absorption rate for red light with a wavelength of 600 nm to 800 nm. In the embodiment of the present application, with the combination of the red filter layer 41 and the green filter layer 42 in the filter layer 40, the red filter layer 41 filters light of other wavelengths, and the red light of a specific wavelength can be received by the corresponding photosensitive device 30, and the green filter layer 42 can filter light of other wavelengths and the green light of a specific wavelength can be received by the corresponding photosensitive device 30. Specifically, the red light with a wavelength of 660 nm and the green light with a wavelength of 535 nm can be used to detect the photoplethysmo graphy (PPG) signals of oxygenated hemoglobin (HbO₂) and reduced hemoglobin (Hb), respectively. According to the difference in the spectral response of oxygenated hemoglobin (HbO₂) and reduced hemoglobin (Hb), the quantitative relationship between reduced hemoglobin (Hb) and oxygenated hemoglobin (HbO₂) can be calculated, and the blood oxygen value can be obtained.

In one of the embodiments, the filter layer 40 comprises two different color filter layers, a red filter layer 41 and a near-infrared filter layer. The red filter layer 41 and the near-infrared filter layer are spaced apart from each other, and respectively correspond to different photosensitive devices 30. The combination of the red filter layer 41 and the near-infrared filter layer can also be applied to blood oxygen detection.

Oxygenated hemoglobin (HbO₂) has a higher absorption rate of near-infrared light with a wavelength of 800 nm to 1000 nm. Reduced hemoglobin (Hb) has a higher absorption rate for red light with wavelengths from 600 nm to 800 nm. In the embodiment of the present application, with the combination of the red filter layer 41 and the near-infrared filter layer in the filter layer 40, the red filter layer 41 filters light of other wavelengths, and the red light of a specific wavelength can be received by the corresponding photosensitive device 30, and the near-infrared filter layer can filter light of other wavelengths and the near-infrared light of a specific wavelength can be received by the corresponding photosensitive device 30. Specifically, the near-infrared light with a wavelength of 940 nm and the red light with a wavelength of 660 nm can be used to detect the PPG signals of oxygenated hemoglobin (HbO₂) and reduced hemoglobin (Hb), respectively. According to the difference in the spectral response of oxygenated hemoglobin (HbO₂) and reduced hemoglobin (Hb), the quantitative relationship between reduced hemoglobin (Hb) and oxygenated hemoglobin (HbO₂) can be calculated, and the blood oxygen value can be obtained.

In one of the embodiments, as shown in FIG. 3, FIG. 3 is a structural diagram of a third optical sensor provided by an embodiment of this application. The structure of the third optical sensor shown in FIG. 3 is substantially the same as the structure of the first optical sensor shown in FIG. 1, except that in the third optical sensor shown in FIG. 3, the color of each of the filter layer 40 is the same.

For instance, the filter layer 40 can be a green filter layer 42, and the green filter layer can filter light of other colors so that green light can pass through and be received by the photosensitive device 30. The green light can be used for heart rate monitoring. Part of the light emitted by the optical sensor will be absorbed by the blood in the blood vessel. The larger the blood volume, the more light will be absorbed, and the less light will be reflected back. With the rhythm of the heart beating, the blood volume in the blood vessels changes, periodically. The intensity of the reflected light detected by the optical sensor changes accordingly, and the heart rate can be calculated according to the change interval of the detected light intensity signal.

The function of the optical sensor provided in the embodiments of the present application is not limited to the heart rate monitoring and blood oxygen detection in the aforesaid embodiments. It is also possible to filter light of different wavelengths (wavelengths between 200 nm to 1200 nm) by combinations with different types of filter layers 40, to achieve monitoring of biological information such as human blood oxygen, heart rate, blood pressure, or the functional filter layer 40 for identification of fingerprints, iris, distance, temperature, etc. In addition, the optical sensor can also realize the function of color separation through the filter layer, which will not be repeated here.

Furthermore, the optical sensor comprises a plurality of accommodating cavities, which are spaced apart. The photosensitive device comprises a photosensitive layer, and the photosensitive layer is arranged in the photosensitive opening. The filter layer is at least partially arranged in the accommodating cavity.

As shown in FIG. 1, in the embodiment of the present application, the photosensitive device 30 is a photodiode, and the photosensitive device 30 comprises a first anode layer 31, a photosensitive layer 32 and a cathode layer 33 stacked in sequence.

The driving circuit layer 20 comprises a first driving circuit 21. The first driving circuit 21 comprises a plurality of thin film transistors, and the photosensitive device 30 is electrically connected to the first driving circuit 21 to realize the photoelectric conversion function under the driving control of the first driving circuit 21.

Specifically, the first driving circuit 21 comprises a first active layer 211, a gate insulating layer 212, a first gate 213, an interlayer dielectric layer 214, a first source 215, a first drain 216 and a planarization layer 217 stacked in sequence on the substrate 10.

The photosensitive device 30 comprises a first anode layer 31, a photosensitive layer 32 and a cathode layer 33. The optical sensor comprises a defining layer 11. The defining layer 11 is arranged on a side of the planarization layer 217 away from the substrate 10.

The defining layer 11 comprises a photosensitive opening 110 spaced apart. The photosensitive opening 110 penetrates the defining layer 11 in a thickness direction of the defining layer 11 and exposes the first anode layer 31 at the bottom of the defining layer 11. The first anode layer 31 is electrically connected to one of the first source 215 and the drain 216 through a via hole penetrating the planarization layer 217.

The photosensitive layer 32 is arranged in the photosensitive opening 110, and is located on a side of the first anode layer 31 away from the substrate 10. The cathode layer 33 is a transparent electrode laid on the entire surface of the defining layer 11 away from the substrate 10, and the cathode layer 33 also covers the photosensitive layer 32.

The cathode layer 33 is made of transparent conductive metal oxide.

Specifically, the metal oxide may be a transparent conductive metal oxide material, such as indium tin oxide (ITO) or indium zinc oxide (IZO).

The optical sensor further comprises an encapsulation layer 12. The encapsulation layer 12 covers a side of the cathode layer 33 away from the substrate 10. The encapsulation layer 12 can be made of any one or more of inorganic materials, such as silicon nitride and silicon oxide.

Since the photosensitive opening 110 possesses a greater depth in the thickness direction of the defining layer 11, and the thickness of the cathode layer 33 and the encapsulation layer 12 is relatively thin, the cathode layer 33 and the encapsulation layer 12 cannot completely fill the photosensitive opening 110, so that the portion of the encapsulation layer 12 corresponding to the photosensitive opening 110 is recessed toward the photosensitive opening 110 and forms the accommodating cavity 50.

In one of the embodiments, as shown in FIG. 2, the filter layer 40 comprises a bottom surface 401 and a top surface 402, and the bottom surface 401 is laid flat on the bottom of the accommodating cavity 50, and the top surface 402 is a curved surface protruding toward a side away from the bottom surface 401. The bottom surface 401 of the filter layer 40 is directly connected to the top surface 402. Neither the bottom surface 401 nor the top surface 402 of the filter layer 40 is in contact with the encapsulation layer 12 located on the side wall of the accommodating cavity 50.

In the embodiment shown in FIG. 2, the filter layer 40 is only arranged in the accommodating cavity 50. An orthographic projection of the filter layer 40 on the substrate 10 may completely overlap with an orthographic projection of the accommodating cavity 50 on the substrate 10, or is covered by the bottom of the orthographic projection of the bottom of the accommodating cavity 50 on the substrate 10.

In the actual preparation process, inkjet printing can be employed to directly print the lens-shaped filter layer 40 in the accommodating cavity 50. Accordingly, the traditional process of preparing the microlens film layer can be omitted. Meanwhile, there is no need to form the color filter layer by photolithography, which can reduce the production process and reduce the production cost.

In one of the embodiments, as shown in FIG. 1, the filter layer 40 comprises a bottom surface 401, a top surface 402 and a side surface 403. The bottom surface 401 is laid flat on the bottom of the accommodating cavity 50, the side surface 403 extends along a side wall of the accommodating cavity 50 and the top surface 402 is a curved surface protruding toward a side away from the bottom surface 402. The side surface 403 is connected to the top surface 401 and the bottom surface 402, respectively. Namely, the bottom surface 401 of the filter layer 40 is in contact with the encapsulation layer 12 located at the bottom of the accommodating cavity 50, and the side surface of the filter layer 40 is in contact with the encapsulation layer 12 located at the sidewall of the accommodating cavity 50.

Compared with the second optical sensor shown in FIG. 1, when the size of the accommodating cavity 50 is the same, the filter layer 40 in the second optical sensor shown in FIG. 2 is also only arranged in the accommodating cavity 50, and does not extend to the encapsulation layer 12 on the outer periphery of the accommodating cavity 50. The orthographic projection of the filter layer 40 on the substrate 10 may cover the orthographic projection of the bottom of the accommodating cavity 50 on the substrate 10, and can completely overlap with the orthographic projection of the top of the accommodating cavity 50 on the substrate 10 or is covered by the orthographic projection of the top of the accommodating cavity 50 on the substrate 10. It can be seen that the light transmission area of the filter layer 40 in the first optical sensor shown in FIG. 1 is larger. This allows the filter layer 40 to converge more light to the corresponding photosensitive device 30, thereby increasing the amount of light entering the photosensitive device 30, thereby further improving the accuracy and sensitivity of the optical sensor.

In one of the embodiments, as shown in FIG. 3, the filter layer 40 comprises a bottom surface 401, a top surface 402 and a side surface 403. The bottom surface 401 is laid flat on the bottom of the accommodating cavity 50. The side surface 403 extends along the side wall of the accommodating cavity 50 to the encapsulation layer 12 on the outer periphery of the accommodating cavity 50, and the side surface 403 is connected to the bottom surface 401 and the top surface 402, respectively. The top surface 402 is a curved surface protruding toward a side away from the bottom surface 402.

In the embodiment shown in FIG. 3, the filter layer 40 does not only fill the accommodating cavity 50, but also extends to the encapsulation layer 12 on the outer periphery of the accommodating cavity 50. The orthographic projection of the filter layer 40 on the substrate 10 can cover the orthographic projection of the accommodating cavity 50 on the substrate 10, that is, the size of the filter layer 40 is greater than the opening size of the accommodating cavity 50. At the same time, the orthographic projection of the filter layer 40 on the substrate 10 and the orthographic projection of any adjacent filter layer 40 on the substrate 10 are spaced apart from each other, so as to avoid overlapping of adjacent filter layers 40 and cause color mixing.

Compared with the first optical sensor shown in FIG. 1, when the size of the accommodating cavity 50 is the same, the light transmission area of the third optical sensor shown in FIG. 3 is further increased, so that the amount of light entering the photosensitive device 30 can be further increased. Thus, on the basis of the first optical sensor shown in FIG. 1, the accuracy and sensitivity of the optical sensor are further improved.

Furthermore, a material of the photosensitive layer 32 comprises at least one of small molecule organic materials, polymer materials and quantum dot materials.

In one of the embodiments, the photosensitive device 30 is an organic photodiode (OPD), and the photosensitive layer 32 in the photosensitive device 30 may be made of one or more of small molecule organic materials, polymer materials and quantum dot materials. In practical applications, the type of the photosensitive device 30 is not limited to the organic photodiode in the aforesaid embodiment, and may also be an inorganic photodiode.

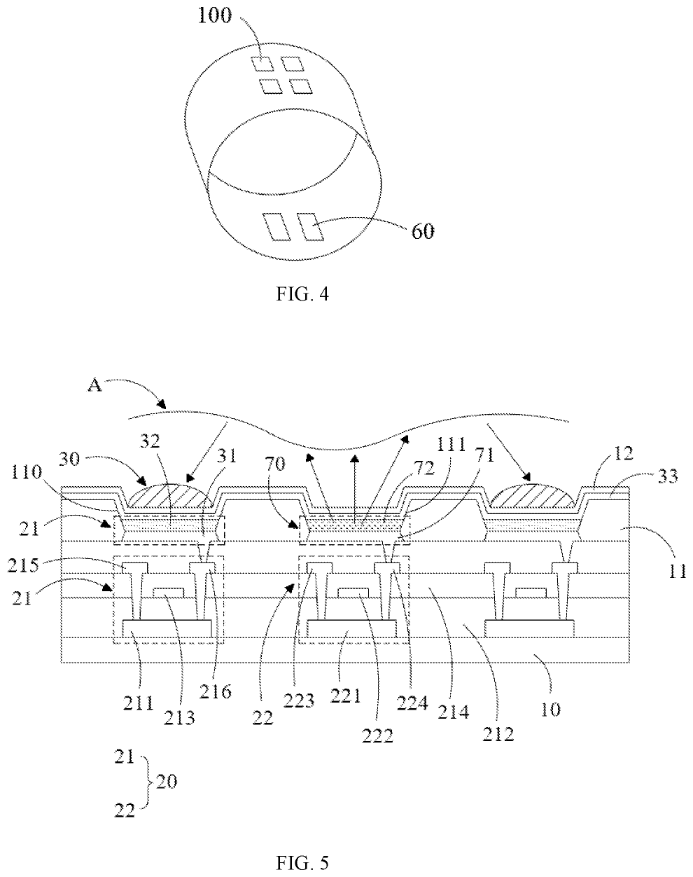

As shown in FIG. 4. FIG. 4 is a structural diagram of a wearable device provided by an embodiment of the application. The wearable device comprises the optical sensor 100 provided in the aforesaid embodiment and a light source 60. The light source 60 and the optical sensor 100 are arranged opposite to each other, and there is a certain accommodating space between the light source 60 and the optical sensor 100, and the accommodating space can be employed to place an identification object.

Specifically, the types of the light source 60 comprises any kinds of light emitting diodes (LEDs), organic light emitting diodes (OLEDs) and vertical-cavity surface-emitting lasers (VCSELs).

As shown in FIG. 5, FIG. 5 is a structural diagram of a display panel provided by an embodiment of the application. The display panel may comprises the optical sensor provided in the aforesaid embodiment.

In the display panel shown in FIG. 5, the display panel further comprises a light-emitting device 70. The light-emitting device 70 is arranged on the substrate 10 and is spaced apart from a photosensitive device 30. In the embodiment of the present application, the substrate 10 may be a conventional base substrate in an existing organic light emitting diode display panel, and the material of the substrate 10 may be a light-transmitting material such as polyimide.

The light-emitting device 70 may be an organic light emitting diode, and the light emitting device 70 may comprise a second anode layer 71, a light-emitting layer 72 and a cathode layer 33 stacked in sequence. The defining layer 11 may be a pixel defining layer commonly used in existing organic light emitting diode display panels, and the defining layer 11 further comprises a plurality of pixel openings 111 arranged spaced apart. The pixel opening 111 penetrates the defining layer 11 in the thickness direction of the defining layer 11 and exposes the second anode layer 71 at the bottom of the defining layer 11, and the light-emitting layer 72 may be arranged inside the pixel opening 111.

The light-emitting device 70 can share the cathode layer 33 with the photosensitive device 30, and the cathode layer 33 covers the light-emitting layer 72. The second anode layer 71 of the light-emitting device 70 and the first anode layer 31 of the photosensitive device 30 are both arranged on the planarization layer 217, and can be formed by the same metal film forming process as the first anode layer 31.

In practical applications, the type of the light-emitting device 70 is not limited to the organic light-emitting diode, and may also be but not limited to a micro light-emitting diode (Micro LED) or a mini light-emitting diode (Mini LED).

The driving circuit layer 20 may further comprise a second driving circuit 22, and the second driving circuit 22 comprises a plurality of thin film transistors. The second anode layer 71 of the light-emitting device 70 is electrically connected to the second driving circuit 22 to emit light under the driving control of the second driving circuit 22.

Specifically, the second driving circuit 22 comprises a second active layer 221, a second gate 222, a second source 223 and a second drain 224. The second active layer 221 and the first active layer 211 are arranged in the same layer. The second active layer 221 and the first active layer 211 can be prepared by the same film forming process. The second gate 222 and the first gate 213 are arranged in the same layer, and the second gate 222 and the first gate 213 can be prepared by the same film forming process. The second source 223 and the second drain 224 are arranged in the same layer as the first source 215 and the first drain 216, and the second source 223 and the second drain 224 can be formed by the same film forming process as the first source 215 and the first drain 216.

In the embodiment of the present application, the color of the light-emitting device 70 comprises but is not limited to red, green and blue. When the photosensitive device 30 is not working, the light-emitting device 70 can emit light under the driving control of the second driving circuit 22, so that the display panel realizes the function of image display. When the photosensitive device 30 is working, the light-emitting device can be employed as the light source to provide light for the photosensitive device 30 to perform optical sensing. Therefore, there is no need to provide an additional light source in the display panel, and no need to prepare holes on the display panel. The photosensitive device 30 and the light-emitting device 70 can be employed to realize functions such as under-screen fingerprint recognition and facial recognition, thereby increasing the screen-to-body ratio of the display panel to achieve the effect of full-screen display.

The display panel provided by the embodiment of the present application can be applied to an electronic device. The electronic device may be a mobile terminal, such as a smart phone, a tablet computer, a notebook computer, etc. The electronic device may also be a wearable terminal, such as a smart watch, a smart bracelet, smart glasses, an augmented reality device, etc. The electronic device may also be a fixed terminal, such as a desktop computer, a television, etc.

The embodiment of the present application provides an optical sensor and a display panel. The display panel comprises the optical sensor, and the optical sensor comprises a substrate, a photosensitive device and a filter layer. The photosensitive device is arranged on the substrate. The filter layer is arranged on a light incident side of the photosensitive device. With arranging the filter layer to have a lens shape, light is converged to the optical sensor. It can not only achieve the absorption of single-band light, but also increase the amount of light entering the optical sensor. Meanwhile, the traditional process of preparing the microlens film layer and the filter layer can be omitted, thereby simplifying the process flow of the optical sensor and the display panel and reducing the production cost.

In summary, although the above preferred embodiments of the present application are disclosed, the foregoing preferred embodiments are not intended to limit the invention, those skilled in the art can make various kinds of alterations and modifications without departing from the spirit and scope of the present application. Thus, the scope of protection of the present application is defined by the scope of the claims.

What is claimed is:

1. An optical sensor, comprising:
a substrate;
a photosensitive device arranged on the substrate; and
a filter layer arranged on a light incident side of the photosensitive device;
wherein the filter layer possesses a lens shape.

2. The optical sensor according to claim 1, wherein the optical sensor comprises a plurality of accommodating cavities, which are spaced apart;
wherein the filter layer is at least partially arranged in the accommodating cavity.

3. The optical sensor according to claim 2, wherein the filter layer comprises a bottom surface and a top surface, and the bottom surface is laid flat on the bottom of the accommodating cavity, and the top surface is a curved surface protruding toward a side away from the bottom surface.

4. The optical sensor according to claim 3, wherein the bottom surface is directly connected to the top surface.

5. The optical sensor according to claim 3, wherein the filter layer further comprises a side surface, and the side surface extends along a side wall of the accommodating cavity and is connected to the top surface and the bottom surface, respectively.

6. The optical sensor according to claim 5, wherein an orthographic projection of the filter layer on the substrate covers an orthographic projection of the accommodating cavity on the substrate;
the orthographic projection of the filter layer on the substrate and an orthographic projection of any adjacent filter layer on the substrate are spaced apart from each other.

7. The optical sensor according to claim 2, wherein the optical sensor comprises a defining layer, the defining layer comprises a photosensitive opening, and the photosensitive opening penetrates the defining layer in a thickness direction of the defining layer;
the photosensitive device comprises a photosensitive layer, and the photosensitive layer is arranged in the photosensitive opening.

8. The optical sensor according to claim 7, wherein the optical sensor further comprises a cathode layer and an encapsulation layer, and the cathode layer and the encapsulation layer are sequentially stacked on a side of the defining layer away from the substrate and cover the photosensitive layer;
wherein a part of the encapsulation layer corresponding to the photosensitive opening is recessed toward the photosensitive opening and forms the accommodating cavity.

9. The optical sensor according to claim 7, wherein a material of the photosensitive layer comprises at least one of small molecule organic materials, polymer materials and quantum dot materials.

10. The optical sensor according to claim 2, wherein the filter layer comprises a combination of at least one or more of a red filter layer, a green filter layer, a blue filter layer and a near-infrared filter layer.

11. A display panel, comprising an optical sensor and a light-emitting device, wherein a light-emitting device is arranged on a substrate and is spaced apart from a photosensitive device;
wherein the optical sensor comprises:
a substrate;
a photosensitive device arranged on the substrate; and
a filter layer arranged on a light incident side of the photosensitive device;
wherein the filter layer possesses a lens shape.

12. The display panel according to claim 11, wherein the optical sensor comprises a plurality of accommodating cavities, which are spaced apart;
wherein the filter layer is at least partially arranged in the accommodating cavity.

13. The display panel according to claim 12, wherein the filter layer comprises a bottom surface and a top surface, and the bottom surface is laid flat on the bottom of the accommodating cavity, and the top surface is a curved surface protruding toward a side away from the bottom surface.

14. The display panel according to claim 13, wherein the bottom surface is directly connected to the top surface.

15. The display panel according to claim 13, wherein the filter layer further comprises a side surface, and the side surface extends along a side wall of the accommodating cavity and is connected to the top surface and the bottom surface, respectively.

16. The display panel according to claim 15, wherein an orthographic projection of the filter layer on the substrate covers an orthographic projection of the accommodating cavity on the substrate;
the orthographic projection of the filter layer on the substrate and an orthographic projection of any adjacent filter layer on the substrate are spaced apart from each other.

17. The display panel according to claim 12, wherein the optical sensor comprises a defining layer, the defining layer comprises a photosensitive opening, and the photosensitive opening penetrates the defining layer in a thickness direction of the defining layer;
the photosensitive device comprises a photosensitive layer, and the photosensitive layer is arranged in the photosensitive opening.

18. The display panel according to claim 17, wherein the optical sensor further comprises a cathode layer and an encapsulation layer, and the cathode layer and the encapsulation layer are sequentially stacked on a side of the defining layer away from the substrate and cover the photosensitive layer;
wherein a part of the encapsulation layer corresponding to the photosensitive opening is recessed toward the photosensitive opening and forms the accommodating cavity.

19. The display panel according to claim 17, wherein a material of the photosensitive layer comprises at least one of small molecule organic materials, polymer materials and quantum dot materials.

20. The display panel according to claim 11, wherein the light-emitting device and the photosensitive device are arranged in a same layer.
